(19) United States
(12) Patent Application Publication
(10) Pub. No.: US 2025/0194326 A1
(43) Pub. Date: Jun. 12, 2025

(54) MICRO LIGHT-EMITTING DIODE DISPLAY DEVICE

(71) Applicant: PlayNitride Display Co., Ltd., Miaoli County (TW)

(72) Inventor: Yun-Li LI, Miaoli County (TW)

(21) Appl. No.: 19/060,989

(22) Filed: Feb. 24, 2025

Related U.S. Application Data
(63) Continuation of application No. 17/517,781, filed on Nov. 3, 2021.

(30) Foreign Application Priority Data
Jun. 21, 2021 (TW) 110122650

(51) Int. Cl. H10H 29/14; H10H 20/857

(52) U.S. Cl. CPC H10H 29/142; H10H 20/857

(57) ABSTRACT

A micro light-emitting diode display device includes a circuit substrate and a plurality of display pixels. The display pixels are arranged on the circuit substrate and are electrically connected to the circuit substrate, respectively. Each of the display pixels includes a plurality of micro light-emitting elements. In each of the display pixels, the micro light-emitting elements form at least one series-connection structure, Wavelengths of the micro light-emitting elements of the series-connection structure are within a wavelength range of the same lighting color. The series-connection structure includes at least two of the micro light-emitting elements which are connected in series. A filling structure is disposed between side walls of the at least two of the micro light-emitting elements, and the circuit substrate respectively provides a driving voltage to drive the micro light-emitting elements included in the series-connection structure of each of the display pixels.

### CROSS REFERENCE TO RELATED APPLICATIONS

This application is a Continuation Application of an earlier filed, pending, application, having application Ser. No. 17/517,781 and filed on Nov. 3, 2021, which claims priority under 35 U.S.C. § 119(a) on patent application No. 110122650 filed in Taiwan, Republic of China on Jun. 21, 2021, the content of which, including drawings, is expressly incorporated by reference herein.

### BACKGROUND

### Technology Field

The present disclosure relates to a display device and, in particular, to a micro light-emitting diode display device.

### Description of Related Art

When the world is paying attention to the future display technology, micro light-emitting diode (micro LED) display device is one of the most promising technologies. In brief, micro LED display device is a technology of miniaturizing and matrixing LED, thereby arranging millions or even tens of millions of dies, which are smaller than 100 microns and thinner than a hair, on a driving substrate.

In order to drive the micro LED display device to emit light, the conventional art is to provide a forward bias (drive voltage) to all electrodes of the micro LEDs through a driving substrate. However, the micro LEDs with different light colors need to be driven by different forward bias. For example, in the driving of the micro LED display device, the forward bias voltage of the micro LED emitting red light is about 1.8 volts, but the forward bias voltages of the micro LEDs emitting green light and blue light are about 3.7 volts. Since the driving substrate needs to provide different drive voltages to the micro LEDs with different light colors, the display device will encounter a problem of relatively high power consumption.

Therefore, it is desired to provide a micro LED display device that can have a lower power consumption.

### SUMMARY

One or more exemplary embodiments of this disclosure are to provide a micro light-emitting diode (LED) display device that can have a lower power consumption.

In an exemplary embodiment, a micro LED display device of this disclosure comprises a circuit substrate and a plurality of display pixels. The display pixels are arranged on the circuit substrate and electrically connected to the circuit substrate, respectively. Each display pixel comprises a plurality of micro light-emitting elements. In each display pixel, a part of the micro light-emitting elements form at least one series-connection structure, and the wavelengths of the micro light-emitting elements of the series-connection structure are within a wavelength range of the same lighting color. The circuit substrate respectively provides the same driving voltage to drive the micro light-emitting elements included in the series-connection structure of each display pixel and the micro light-emitting elements excluded from the series-connection structure.

In one embodiment, the series-connection structure comprises at least two of the micro light-emitting elements, which are connected in series.

In one embodiment, the wavelengths of the at least two of the micro light-emitting elements are greater than wavelengths of the micro light-emitting elements excluded from the series-connection structure.

In one embodiment, a difference of wavelengths of the at least two of the micro light-emitting elements included in the series-connection structure is less than 2 nm.

In one embodiment, a distance between the at least two of the micro light-emitting elements included in the series-connection structure is less than a distance between any one of the micro light-emitting elements included in the series-connection structure and any one of the micro light-emitting elements excluded from the series-connection structure, or between any two of the micro light-emitting elements excluded from the series-connection structure.

In one embodiment, a lighting area of any one of the micro light-emitting elements included in the series-connection structure is less than or equal to a lighting area of any one of the micro light-emitting elements excluded from the series-connection structure.

In one embodiment, a sum of lighting areas of the at least two of the micro light-emitting elements included in the series-connection structure is greater than a lighting area of any one of the micro light-emitting elements excluded from the series-connection structure.

In one embodiment, the series-connection structure further comprises a conductive layer, and the conductive layer connects in series with the at least two of the micro light-emitting elements included in the series-connection structure.

In one embodiment, the series-connection structure further comprises an insulating layer, and the insulating layer is configured between the circuit substrate and a part of the conductive layer.

In one embodiment, a part of the conductive layer directly contacts the circuit substrate.

In one embodiment, a maximum vertical distance between the conductive layer and a surface of the circuit substrate is less than or equal to 6 μm.

In one embodiment, each of the micro light-emitting elements comprises a first type semiconductor layer, a light-emitting layer and a second type semiconductor layer stacked in order, and the first type semiconductor layers or the second type semiconductor layers of the micro light-emitting elements included in the series-connection structure are a common layer.

In one embodiment, in each display pixel, a number of the micro light-emitting elements emitting red light is greater than a number of the micro light-emitting elements emitting green light or blue light.

In one embodiment, the series-connection structure further comprises a conductive layer and an insulating layer, the conductive layer connects in series with the at least two of the micro light-emitting elements included in the series-connection structure, and a part of the insulating layer is configured between a part of the conductive layer and the at least two of the micro light-emitting elements included in the series-connection structure.

In one embodiment, the micro LED display device further comprises a filling structure disposed between side walls of the at least two of the micro light-emitting elements.

In one embodiment, a surface of the filling structure is a light reflection surface or a light absorption surface.

As mentioned above, in the micro LED display device of this disclosure, a part of the micro light-emitting elements in each display pixel can form at least one series-connection structure, and the wavelengths of the micro light-emitting elements of the series-connection structure are within a wavelength range of the same lighting color. In addition, the circuit substrate respectively provides the same driving voltage to drive the micro light-emitting elements included in the series-connection structure of each of the display pixels and the micro light-emitting elements excluded from the series-connection structure. Compared with the conventional micro LED display device having relative high power consumption, this disclosure can provide the same driving voltage to drive the micro light-emitting elements included in and excluded from the series-connection structure in each display pixel, so that the micro LED display device of this disclosure can have relative low power consumption.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a schematic diagram showing a micro LED display device according to an embodiment of this disclosure.

FIG. 1B is a sectional view of the micro LED display device of FIG. 1A along the line A-A.

FIGS. 2A to 2F are schematic diagrams showing the micro LED display devices of different embodiments of this disclosure.

FIG. 3 is a schematic diagram showing a micro LED display device according to another embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

To be noted, the micro LED display device 1 of this embodiment can be an AM (Active Matrix) or PM (Passive Matrix) micro LED display device, but this disclosure is not limited thereto. In addition, the symbol R, R1 or R2 shown in the following embodiments represents a micro light-emitting element, or a micro light-emitting element emitting red light, the symbol G, G1 or G2 shown in the following embodiments represents a micro light-emitting element, or a micro light-emitting element emitting green light, and the symbol B, B1 or B2 shown in the following embodiments represents a micro light-emitting element, or a micro light-emitting element emitting blue light. The definitions of these symbols depend on the application circumstances and situations. In this disclosure, the micro light-emitting elements are micro LEDs.

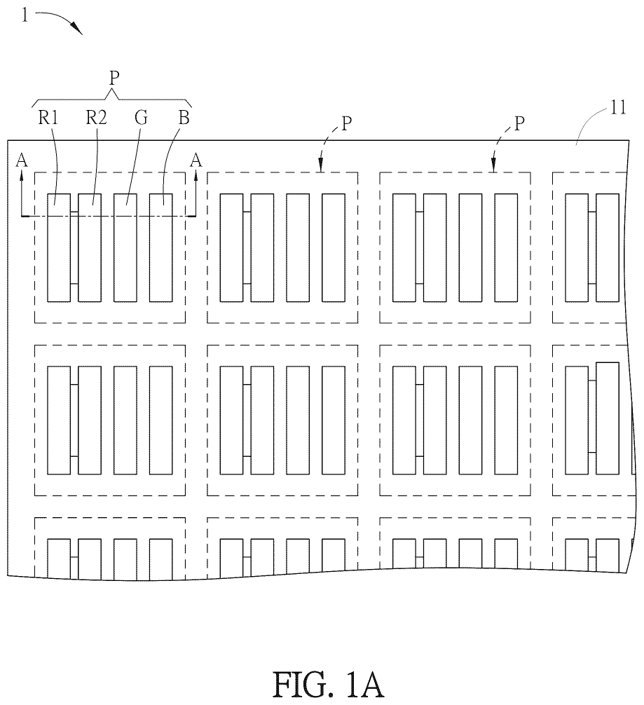

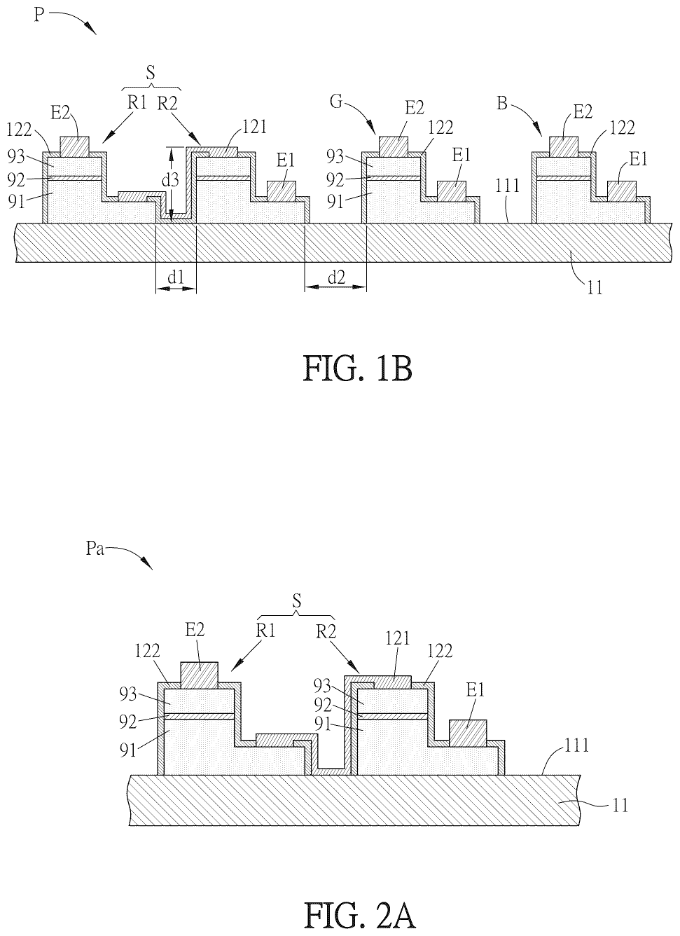

FIG. 1A is a schematic diagram showing a micro LED display device according to an embodiment of this disclosure, and FIG. 1B is a sectional view of the micro LED display device of FIG. 1A along the line A-A. Herein, FIG. 1A shows that the micro LED display device 1 comprises a plurality of display pixels P (or pixel), and FIG. 1B shows the structure of a display pixel P.

Referring to FIGS. 1A and 1B, the micro LED display device 1 comprises a circuit substrate 11 and a plurality of display pixels P, and the display pixels are arranged on the circuit substrate 11. In this embodiment, the pixels P are arranged in a matrix of rows and columns. In this embodiment, the display pixels P are arranged in a matrix including rows and columns and disposed on the circuit substrate 11, and the display pixels P are electrically connected to the circuit substrate 11, respectively. Accordingly, the display pixels P can be driven, through the circuit substrate 11, to emit light of the corresponding colors. Each display pixel P comprises a plurality of micro light-emitting element (i.e. micro LEDs). Herein, each display pixel P comprises at least four micro light-emitting elements. In this embodiment, for example, each display pixel P comprises four micro light-emitting elements R1, R2, G and B. Of course, this disclosure is not limited thereto. In other embodiments, each display pixel P may comprise more than four micro light-emitting elements. For example, each display pixel P may comprise five micro light-emitting elements, such as five micro light-emitting elements R1, R2, G1, G2 and B, or five micro light-emitting elements R1, R2, G, B1 and B2. Of course, each display pixel P may comprise multiple micro light-emitting elements of other numbers and colors.

In some embodiments, the circuit substrate 11 can comprise a plurality of conductive pattern layers and/or circuit layers (not shown), and the circuit substrate 11 can transmit electric signals (e.g. the driving voltage) to the sub-pixels of the display pixels P through the corresponding conductive pattern layers and/or circuit layers for driving the micro light-emitting elements to emit light. In some embodiments, the circuit substrate 11 may be, for example, a Complementary Metal-Oxide-Semiconductor (CMOS) substrate, a Liquid Crystal on Silicon (LCOS) substrate, or a thin film transistor (TFT) substrate, or any of other driving substrates with working circuits, to drive the micro light-emitting elements to emit the corresponding color lights. In some embodiments, the length of the circuit substrate 11 can be, for example but not limited to, less than or equal to 1 inch, and the PPI (pixels per inch) thereof can be greater than 1000. Of course, in other embodiments, the length of the circuit substrate 11 can be greater than 1 inch, and the PPI thereof is not limited.

As shown in FIG. 1B, in each display pixel P, a part of the micro light-emitting elements form at least one series-connection structure S. Herein, the series-connection structure S is composed of at least two micro light-emitting elements, which are connected in series. In this embodiment, the series-connection structure S is composed of two micro light-emitting elements connected in series. In other embodiments, the series-connection structure S can be composed of three or more micro light-emitting elements connected in series (e.g. four micro light-emitting elements connected in series). Specifically, the series-connection structure S of this embodiment comprises two micro light-emitting elements (e.g. R1 and R2), and the wavelengths of the micro light-emitting elements R1 and R2 of the series-connection structure S are within a wavelength range of the same lighting color. Preferably, the difference of wavelengths of the two micro light-emitting elements R1 and R2 is less than 2 nm. This configuration can achieve a better display effect. In this embodiment, the micro light-emitting elements R1 and R2 of the series-connection structure S are configured to emit red light (e.g. having the wavelength between 620 nm and 670 nm). To be noted, this disclosure is not limited thereto. In other embodiments, the micro light-emitting elements included in the series-connection structure S can emit green light or blue light.

The micro light-emitting elements R1, R2, G and B of the display pixels P are arranged on the circuit substrate 11, and each of the micro light-emitting elements R1, R2, G and B comprises a first type semiconductor layer 91, a light-emitting layer 92, and a second type semiconductor layer 93, which are stacked in order. The first type semiconductor layer 91 is disposed on the surface 111 of the circuit substrate 11, and the light-emitting layer 92 is sandwiched between the first type semiconductor layer 91 and the second type semiconductor layer 93. In this embodiment, the light-emitting layer 92 can be, for example, a multiple quantum well (MQW) layer, the first type semiconductor layer 91 can be, for example, an N-type semiconductor, and the second type semiconductor layer 93 can be, for example, a P-type semiconductor. To be noted, this disclosure is not limited thereto. In this embodiment, the micro light-emitting elements R1, R2, G and B of the display pixels P can be horizontal-type micro LEDs, but this disclosure is not limited thereto. In other embodiments, the micro light-emitting elements R1, R2, G and B can be vertical-type micro LEDs or flip-chip type micro LEDs.

In order to drive the micro light-emitting elements R1, R2, G and B to emit light, each of the series-connection structure S and the micro light-emitting elements G and B in each display pixel P is configured with a first electrode E1 and a second electrode E2, which are electrically connected to the circuit substrate 11. In addition, in order to connect the two micro light-emitting elements R1 and R2 in series, the series-connection structure S of this embodiment further comprises a conductive layer 121 and an insulating layer 122. The conductive layer 121 is disposed on the circuit substrate 11 and is configured to connect the two micro light-emitting elements R1 and R2 included in the series-connection structure S in series. The insulating layer 122 is configured between the circuit substrate 11 and a part of the conductive layer 121. In this embodiment, the conductive layer 121 covers a part of the insulating layer 122 and parts of the micro light-emitting elements R1 and R2, and the conductive layer 121 simultaneously electrically connects the first type semiconductor layer 91 of the micro light-emitting element R1 to the second type semiconductor layer 93 of the micro light-emitting element R2. Moreover, on the surfaces of the micro light-emitting elements R1, R2, G and B away from the circuit substrate 11, the regions that are not configured with the first electrode E1, the second electrode E2 or the conductive layer 121 are all covered by the insulating layer 122. This configuration can provide the insulation effect and further protect the micro light-emitting elements R1, R2, G and B from the external moisture and dusts.

To be noted, in each display pixel P of this embodiment, the series-connection circuit (including the conductive layer 121 and the insulating layer 122) for connecting the micro light-emitting elements R1 and R2 in series is arranged between two micro light-emitting elements R1 and R2 instead of disposing on the circuit substrate 11. Thus, the conductive layer 121, the insulating layer 122 and the micro light-emitting elements R1 and R2 can together form the series-connection structure S (i.e., the series-connection structure S comprises the conductive layer 121, the insulating layer 122 and two micro light-emitting elements R1 and R2), which are electrically connected to the circuit substrate 11 via the connection pads (not shown) on the circuit substrate 11. Accordingly, in this embodiment, the series-connection structure can be formed before transferring huge amount of micro light-emitting elements on to the circuit substrate. When the micro light-emitting elements are minimized to the scale of less than 50 μm, the configuration of the series-connection structures can improve the connection between two micro light-emitting elements and increase the production yield of the transferring process. Moreover, since the series-connection structures are composed of the micro light-emitting elements of the same area and are formed before the transferring process, the difference of wavelengths of the micro light-emitting elements included in the same series-connection structure can be smaller (e.g., less than 2 nm). This configuration can achieve a better display effect without sorting the micro light-emitting elements before the transferring process.

In each display pixel P of this embodiment, the first type semiconductor layer 91 of the micro light-emitting element R2 of the series-connection structure S is connected to the first electrode E1, the second type semiconductor layer 93 of the micro light-emitting element R1 of the series-connection structure S is connected to the second electrode E2, and the first electrode E1 and the second electrode E2 are electrically connected to the corresponding connection pads and/or circuit layers of the circuit substrate 11 via additional connective layers (not shown) configured between the electrodes E1 and E2 respectively. Therefore, the driving voltage (a first driving voltage) can be provided from the circuit substrate 11 to the first electrode E1 and the second electrode E2 for driving the micro light-emitting elements R1 and R2 to emit red light. In addition, in each display pixel P of this embodiment, the micro light-emitting elements excluded from the series-connection structure S comprise the micro light-emitting elements G and B. The first type semiconductor layers 91 of the micro light-emitting elements G and B are connected to the first electrode E1, the second type semiconductor layers 93 of the micro light-emitting elements G and B are connected to the second electrode E2, and the first electrode E1 and the second electrode E2 are electrically connected to the corresponding conductive pads and/or circuit layers of the circuit substrate 11 via additional connective layers (not shown) configured between the electrodes E1 and E2 respectively. Therefore, the same driving voltage (a second driving voltage) can be provided from the circuit substrate 11 to the first electrode E1 and the second electrode E2 for driving the micro light-emitting elements G and B to emit green light and blue light, respectively. The configuration of the above-mentioned series-connection structure S can increase the cross voltage between micro light-emitting elements, so that the first driving voltage and the second driving voltage can be the same (e.g. all equal to 3.7 volts).

Therefore, when the micro LED display device 1 is enabled, for example, the second electrode E2 can have a high potential, and the first electrode E1 can have a ground potential or a low potential. The current generated by the potential difference between the second electrode E2 and the first electrode E1 (i.e., the driving voltage) can enable the corresponding series-connection structure S and the micro light-emitting elements G and B excluded from the series-connection structure S to emit the corresponding red light, green light and blue light. More specifically, the micro LED display device 1 can be controlled by the driving element (e.g., an active element such as TFT) of the circuit substrate 11, and the corresponding conductive patterns and/or circuit layers can make the corresponding second electrodes E2 have different height potentials, thereby driving the micro light-emitting elements R1 and R2 included in the series-connection structure S and the micro light-emitting elements G and B excluded from the series-connection structure S to emit light beams of different colors (red, green and blue) and different intensities. The spatial distribution of these light beams with different colors and different intensities can form an image that can be seen by viewers, so that the micro LED display device 1 can function as a full-color display device.

The above-mentioned conductive layer 121 can comprise a metal material, a transparent conductive material, or a combination thereof, but this disclosure is not limited thereto. In this embodiment, the metal material may comprise, for example, aluminum, copper, silver, molybdenum, or titanium, or an alloy thereof, and the transparent conductive material may comprise, for example, indium tin oxide (ITO), indium zinc oxide (IZO), aluminum zinc oxide (AZO), cadmium tin oxide (CTO), tin oxide (SnO₂), zinc oxide (ZnO), or any of other transparent conductive materials. In addition, the above-mentioned insulating layer 122 can be made of an organic material (e.g., a structural photoresist) or an inorganic material (e.g., silicon dioxide or silicon nitride), but this disclosure is not limited thereto.

In some embodiments, in the direction perpendicular to the surface 111 of the circuit substrate 11 (i.e., the top view direction of the circuit substrate 11), the length of each micro light-emitting element (e.g., R1, R2, G or B) can be, for example, less than or equal to 60 μm. In some embodiment, the distance (or pitch) between two micro light-emitting elements (e.g. R1 and R2) of the series-connection structure S is less than the distance between any one of the micro light-emitting elements included in the series-connection structure S and any one of the micro light-emitting elements excluded from the series-connection structure S (e.g. G and B), or between any two of the micro light-emitting elements excluded from the series-connection structure S. In this embodiment, as shown in FIG. 1B, the distance d1 between the micro light-emitting elements R1 and R2 of the series-connection structure S is less than the distance d2 between the micro light-emitting elements R2 and G or the distance between the micro light-emitting elements G and B. In some embodiments, the distance d1 between the micro light-emitting elements (e.g., R1 and R2) of the series-connection structure S can be less than 10 μm, and preferably less than 5 μm, thereby achieving a better display resolution. In some embodiments, the maximum vertical distance d3 between the conductive layer 121 and the surface 111 of the circuit substrate 11 (i.e., the vertical distance between the highest point of the conductive layer 121 and the surface 111 of the circuit substrate 11) is less than or equal to 6 μm, and preferably less than 2 μm. In some embodiments, the wavelengths of the two micro light-emitting elements (e.g., R1 and R2) of the series-connection structure S is greater than the wavelengths of the micro light-emitting elements (e.g., G and B) excluded from the series-connection structure S. In some embodiments, the lighting area of any one of the micro light-emitting elements (e.g., R1 and R2) included in the series-connection structure S is less than or equal to the lighting area of any one of the micro light-emitting elements (e.g., G and B) excluded from the series-connection structure S. In some embodiments, the sum of the lighting areas of the two micro light-emitting elements (e.g., R1 and R2) included in the series-connection structure S is equal to the lighting area of any one of the micro light-emitting elements (e.g., G and B) excluded from the series-connection structure S. In some embodiments, the sum of the lighting areas of the two micro light-emitting elements (e.g., R1 and R2) included in the series-connection structure S is greater than the lighting area of any one of the micro light-emitting elements (e.g., G and B) excluded from the series-connection structure S (this is because that the luminous efficiency of red-light micro light-emitting elements R1 and R2 is relatively lower).

In addition, in each display pixel P of this embodiment, the two red-light micro light-emitting elements R1 and R2 are connected in series, and the green-light and blue-light micro light-emitting elements G and B are individual components (which are not connected to the adjacent micro light-emitting element in series or in parallel). Accordingly, in each display pixel P or display pixels P, the number of the red-light micro light-emitting elements R1 and R2 is greater than the number of the green-light or blue-light micro light-emitting element(s) G or B. For example, the ratio of the numbers of the red, green and blue micro light-emitting elements is 2:1:1. This configuration can provide the optimum display efficiency and decrease the power consumption.

As mentioned above, in the micro LED display device 1 of this embodiment, the micro light-emitting elements R1 and R2 of each display pixel P can form a series-connection structure S, and the wavelengths of the micro light-emitting elements R1 and R2 of the series-connection structure S are within a wavelength range of the same lighting color. In addition, the circuit substrate 11 can respectively provide the same driving voltage to drive the micro light-emitting elements R1 and R2 included in the series-connection structure S and the micro light-emitting elements G and B excluded from the series-connection structure S of each display pixel P. Accordingly, the same driving voltage can not only drive the micro light-emitting elements R1 and R2 included in the series-connection structure S in each display pixel P, but also drive the micro light-emitting elements G and B excluded from the series-connection structure S in each display pixel P. For example, the circuit substrate 11 can provide a 3.7 V driving voltage to the display pixel P for driving the micro light-emitting elements R1 and R2 included in the series-connection structure S to emit red light, driving the micro light-emitting element G excluded from the series-connection structure S to emit green light, and driving the micro light-emitting element B excluded from the series-connection structure S to emit blue light. As a result, comparing with the above-mentioned conventional micro LED display device having relative high power consumption, the micro LED display device 1 of this embodiment can have a relative low power consumption.

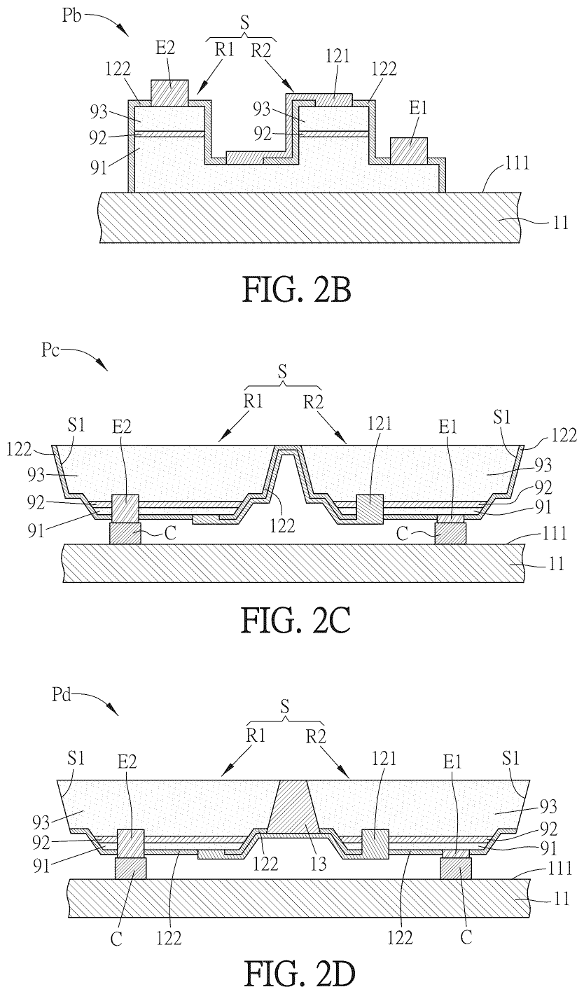

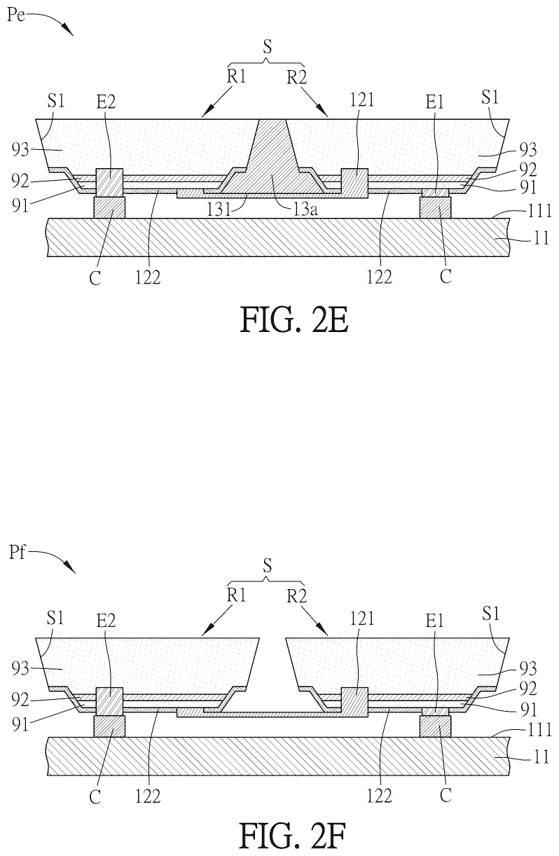

FIGS. 2A to 2F are schematic diagrams showing the micro LED display devices of different embodiments of this disclosure. To be noted, FIGS. 2A to 2F only show the series connection structures of one display pixels Pa-Pf in the micro LED display devices.

As shown in FIG. 2A, the component configurations and connections of the micro LED display device of this embodiment are mostly the same as those of the previous embodiment. Different from the previous embodiment, in each display pixel Pa of the micro LED display device of this embodiment as shown in FIG. 2A, a part of the conductive layer 121 disposed between two micro light-emitting elements R1 and R2 directly contacts the circuit substrate 11. To be noted, in order to prevent the short circuit between the conductive layer 121 and the circuit substrate 11, the circuit substrate 11 must be configured with an insulating material for insulating the conductive layer 121 and the conductive circuit of the circuit substrate 11. In this embodiment, the series-connection structure S can be formed after the two micro light-emitting elements R1 and R2 are transferred to the circuit substrate 11, and this disclosure is not limited thereto.

As shown in FIG. 2B, the component configurations and connections of the micro LED display device of this embodiment are mostly the same as those of the previous embodiment. Different from the previous embodiment, in each display pixel Pb of the micro LED display device of this embodiment as shown in FIG. 2B, the first type semiconductors of the two micro light-emitting elements R1 and R2 of the series-connection structure S are connected to each other. In other words, the micro light-emitting elements R1 and R2 comprise a common first type semiconductor layer 91 (e.g. an N-type semiconductor layer). Since the micro light-emitting elements R1 and R2 are an integrated component, and they are not needed to be separated in advance, so that the pitch between the micro light-emitting elements R1 and R2 can be further reduced. This configuration can improve the usage rate, and increase the connection force during the huge-amount transferring so as to obtain a higher transferring yield. Of course, in different embodiments, the micro light-emitting elements R1 and R2 may comprise a common second type semiconductor layer 93 (e.g. a P-type semiconductor layer), and this disclosure is not limited.

As shown in FIG. 2C, the component configurations and connections of the micro LED display device of this embodiment are mostly the same as those of the previous embodiment. Different from the previous embodiment, in each display pixel Pc of the micro LED display device of this embodiment as shown in FIG. 2C, the micro light-emitting elements R1, R2, G and B are all flip-chip type micro LEDs. Accordingly, the first electrode E1 and the second electrode E2 of the series-connection structure S can be electrically connected to the circuit substrate 11 via the connection pads C on the circuit substrate 11.

Besides, in order to prevent the short circuit between the conductive layer 121 and the flip-chip type micro light-emitting elements R1 and R2 of the series-connection structure S, the series connection design is needed and, moreover, the insulating layer 122 is also required to be configured between the conductive layer 121 and the flip-chip type micro light-emitting elements R1 and R2 before forming the conductive layer 121. In other words, a part of the insulating layer 122 must be disposed between a part of the conductive layer 121 and the micro light-emitting elements R1 and R2 of the series-connection structure S, thereby preventing the short circuit between the conductive layer 121 and the side walls S1 of the micro light-emitting elements R1 and R2. In addition, the side walls S1 of the micro light-emitting elements R1 and R2 is formed with a stepwise structure. This design can reduce the gaps during the manufacturing process, so that the circuit of the series-connection structure S (the conductive layer 121 and the insulating layer 122) can be formed easier.

As shown in FIG. 2D, the component configurations and connections of the micro LED display device of this embodiment are mostly the same as those of the previous embodiment. Different from the previous embodiment, in each display pixel Pd of the micro LED display device of this embodiment as shown in FIG. 2D, the micro LED display device further comprises a filling structure 13 disposed between the side walls S1 of the two micro light-emitting elements R1 and R2 of the series-connection structure S and contacting the side walls S1 between the micro light-emitting elements R1 and R2. When the micro light-emitting elements R1 and R2 are smaller than or equal to 50 μm, the bottom half of the stepwise design will reduce the spatial usage rate, so that the filling structure 13 is introduced therebetween. The configuration of the filling structure 13 can reduce the gaps of the micro light-emitting elements R1 and R2, thereby decreasing the difficulty for manufacturing the conductive layer 121 and the insulating layer 122 and increasing the usage rate of the micro light-emitting elements. In some embodiments, the filling structure 13 is made of insulation material. In some embodiments, the filling structure 13 comprises an inorganic material (for example but not limited to silicon dioxide). In some embodiments, the filling structure 13 comprises an organic material (e.g., organic photoresist). In some embodiments, the surface of the filling structure 13 (i.e., the part of the filling structure 13 contacting the micro light-emitting elements R1 and R2) can be configured with a reflective material for forming a light reflection surface, which can increase the light output efficiency of the micro light-emitting elements R1 and R2. In some embodiments, the surface of the filling structure 13 can be configured with a light absorption material (e.g., a black photoresist) for forming a light absorption surface, which can prevent the interference between the outputted light beams. Furthermore, the filling structure 13 can increase the structural supporting force of the micro light-emitting elements R1 and R2, especially during the transferring process, thereby further improving the transferring yield. Moreover, if a light conversion structure (not shown, such as quantum dots) is provided on the micro light-emitting elements R1 and R2 in the following process, the planar upper surface can further improve the manufacturing yield.

As shown in FIG. 2E, the component configurations and connections of the micro LED display device of this embodiment are mostly the same as those of the previous embodiment. Different from the previous embodiment, in each display pixel Pe of the micro LED display device of this embodiment as shown in FIG. 2E, the filling structure 13a is disposed between the side walls S1 of the micro light-emitting elements R1 and R2 and further extending toward the circuit substrate 11, so that the surface 131 of the filling structure 13a facing the circuit substrate 11 can be a planar surface. Accordingly, the conductive layer 121 can be easily formed on the planar surface 131. In addition, the filling structure 13a can also increase the structural supporting force of the micro light-emitting elements R1 and R2, especially during the transferring process, thereby further improving the transferring yield. Moreover, if a light conversion structure (not shown, such as quantum dots) is provided on the micro light-emitting elements R1 and R2 in the following process, the planar upper surface can further improve the manufacturing yield.

In addition, after the series-connection structure S is formed, the above-mentioned filling structure 13a (or the filling structure 13) can be removed based on the display requirement so as to remain the empty connection as shown in the display pixel Pf of FIG. 2F.

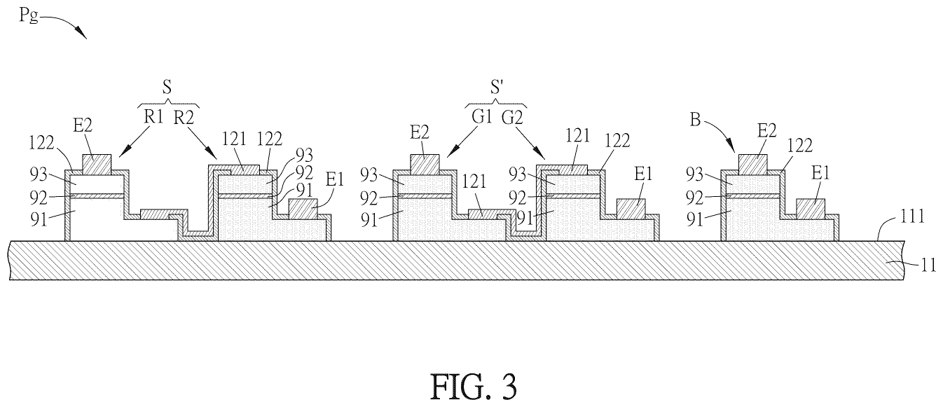

FIG. 3 is a schematic diagram showing a micro LED display device according to another embodiment of this disclosure. To be noted, FIG. 3 only shows the series connection structure of one display pixels Pg in the micro LED display device.

As shown in FIG. 3, the component configurations and connections of the micro LED display device of this embodiment are mostly the same as those of the previous embodiment. Different from the previous embodiment, as shown in FIG. 3, the display pixel Pg of the micro LED display device of this embodiment further comprises another series-connection structure S′. In this embodiment, the series-connection structure S′ comprises a plurality of micro light-emitting elements, which are connected in series. For example, the series-connection structure S′ comprises two micro light-emitting elements G1 and G2 connected in series. The wavelengths of the micro light-emitting elements G1 and G2 of the series-connection structure S′ are within a wavelength range of the same lighting color (e.g., green). Preferably, the difference of wavelengths of the two micro light-emitting elements G1 and G2 is less than 2 nm. Similarly, the circuit substrate 11 can provide the same driving voltage (e.g., 3.7 volts) to drive the micro light-emitting elements included in the series-connection structures S and S′ of each display pixel Pg and the micro light-emitting elements (e.g., the micro light-emitting element B) excluded from the series-connection structures S and S′ of each display pixel Pg. This configuration can achieve the purpose of decreasing the power consumption. In this embodiment, it is unnecessary to design three or more circuits when it is needed to provide the lighting displaying effect (e.g., it needs to enable multiple green micro light-emitting elements to emit green light) and to simultaneously change the circuit design of the circuit substrate to drive the series-connection structures S and S′. As a result, this embodiment can achieve the purpose of decreasing the power consumption and reduce the design difficulty of the driving circuit.

In some embodiments, the two blue-light micro light-emitting elements can construct another series-connection structure. In some embodiments, the two green-light micro light-emitting elements can construct another series-connection structure, and the two blue-light micro light-emitting elements can further construct still another series-connection structure. In some embodiments, the numbers of the micro light-emitting elements connected in series in different series-connection structures of different colors can be the same or different (e.g., four red micro light-emitting elements connected in series, two green micro light-emitting elements connected in series, and two blue micro light-emitting elements connected in series). In some embodiments, the lighting areas of different series-connection structures of different colors can be the same or different, and this disclosure is not limited.

In summary, a part of the micro light-emitting elements in each display pixel can form at least one series-connection structure, and the wavelengths of the micro light-emitting elements of the series-connection structure are within a wavelength range of the same lighting color. In addition, the circuit substrate respectively provides the same driving voltage to drive the micro light-emitting elements included in the series-connection structure of each of the display pixels and the micro light-emitting elements excluded from the series-connection structure. Compared with the conventional micro LED display device having relative high power consumption, this disclosure can provide the same driving voltage to drive the micro light-emitting elements included in and excluded from the series-connection structure in each display pixel, so that the micro LED display device of this disclosure can have relative low power consumption.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A micro light-emitting diode display device, comprising:
a circuit substrate; and
a plurality of display pixels arranged on the circuit substrate and electrically connected to the circuit substrate, respectively, wherein each of the display pixels comprises a plurality of micro light-emitting elements;
wherein, in each of the display pixels, the micro light-emitting elements form at least one series-connection structure, wavelengths of the micro light-emitting elements of the series-connection structure are within a wavelength range of the same lighting color, the series-connection structure comprises at least two of the micro light-emitting elements which are connected in series, a filling structure is disposed between side walls of the at least two of the micro light-emitting elements, and the circuit substrate respectively provides a driving voltage to drive the micro light-emitting elements included in the series-connection structure of each of the display pixels.

2. The micro light-emitting diode display device of claim 1, wherein the series-connection structure further comprises a conductive layer and an insulating layer, the conductive layer connects in series with the at least two of the micro light-emitting elements included in the series-connection structure, and a part of the insulating layer is configured between a part of the conductive layer and the at least two of the micro light-emitting elements included in the series-connection structure.

3. The micro light-emitting diode display device of claim 1, wherein a surface of the filling structure is a light reflection surface or a light absorption surface.

4. The micro light-emitting diode display device of claim 1, wherein each of the micro light-emitting elements comprises a first type semiconductor layer, a light-emitting layer and a second type semiconductor layer, the light-emitting layer, the first type semiconductor layer and one portion of the second type semiconductor layer in each of the micro light-emitting elements of the series-connection structure form a protruding portion.

5. The micro light-emitting diode display device of claim 4, wherein the filling structure is completely filled in a space between the other portion of the second-type semiconductor layers of the at least two of the micro light-emitting elements in the series-connected structure.

6. The micro light-emitting diode display device of claim 4, wherein the second-type semiconductor layers of the at least two of the micro light-emitting elements have surfaces that are distal from the circuit substrate and are flush with the filling structure.

7. The micro light-emitting diode display device of claim 1, wherein the filling structure is an insulating material.

8. The micro light-emitting diode display device of claim 1, wherein the series-connection structure further comprises a first electrode and a second electrode, which are disposed on different micro light-emitting elements of the series-connection structure, the first electrode and the second electrode have different electrical properties.

9. The micro light-emitting diode display device of claim 8, the first electrode and the second electrode are electrically connected to the circuit substrate via connection pads, respectively, to receive the driving voltage provided by the circuit substrate through the first electrode and the second electrode.
